(19) United States
(12) Patent Application Publication
(10) Pub. No.: US 2024/0110659 A1
(43) Pub. Date: Apr. 4, 2024

(54) KNIT TUBULAR THERMAL SLEEVE WITH WRAPPABLE COVER AND METHOD OF CONSTRUCTION THEREOF

(71) Applicant: FEDERAL-MOGUL POWERTRAIN LLC, Northville, MI (US)

(72) Inventors: Scott McFarland, Maumelle, AR (US); Xiaodan Qiu, Phoenixville, PA (US); Jordan Boatwright, York, PA (US)

(21) Appl. No.: 18/374,616

(22) Filed: Sep. 28, 2023

Related U.S. Application Data
(60) Provisional application No. 63/411,709, filed on Sep. 30, 2022.

(51) Int. Cl. F16L 59/02; D04B 1/16; D04B 1/22; D04B 21/16; D04B 21/20; H01B 7/29; H05K 9/00

(52) U.S. Cl. CPC F16L 59/026; D04B 1/16; D04B 1/22; D04B 21/16; D04B 21/20; H01B 7/292; H05K 9/009; H05K 9/0098; D10B 2101/00; D10B 2401/04; D10B 2401/06; D10B 2505/00

(57) ABSTRACT

A knit sleeve for providing thermal protection about an elongate member contained therein and method of construction thereof is provided. The sleeve includes a circumferentially continuous, tubular knit inner wall bounding a central cavity that extends lengthwise along a longitudinal central axis between open opposite ends. The sleeve further includes a knit outer wall with opposite edges extending lengthwise in generally parallel relation with the longitudinal central axis, with one of the opposite edges of the knit outer wall being integrally knit to the inner wall and the other of the opposite edges of the outer wall being wrappable about the inner wall into fixed relation about the inner wall.

### CROSS-REFERENCE TO RELATED APPLICATION

This application claims the benefit of U.S. Provisional Application Ser. No. 63/411,709, filed Sep. 30, 2022, which is incorporated herein by reference in its entirety.

### BACKGROUND OF THE INVENTION

### 1. Technical Field

This invention relates generally to tubular protective sleeves for providing protection to elongate members contained therein, and more particularly to knit tubular protective sleeves for providing a thermal insulation barrier about high temperature pipes and to their method of construction.

### 2. Related Art

Tubular sleeves are known for insulating elongate members, such as high temperature elongate members. The sleeves are commonly constructed from heat resistant yarns, such as silica, fiberglass, ceramic, basalt, aramid or carbon, to withstand relatively high temperatures. Tubular sleeves constructed from such heat-resistant yarns are commonly used to insulate high temperature tubes, such as those providing a conduit for hot liquid or gas, such as exhaust gases, to inhibit the heat from radiating outwardly beyond the confines of the tubing. Although the tubular sleeves discussed above are generally effective in providing a thermal barrier, the heat-resistant yarn that forms the outer wall of the sleeves is susceptible to damage, and thus, the useful life of the sleeves can be diminished.

### SUMMARY OF THE INVENTION

In accordance with one aspect of the invention, a sleeve for providing thermal protection about an elongate member contained therein is provided. The sleeve includes a circumferentially continuous, tubular knit inner wall bounding a central cavity that extends lengthwise along a longitudinal central axis between open opposite ends. The sleeve further includes a knit outer wall with opposite edges extending lengthwise between the opposite open ends, with one of the opposite edges of the knit outer wall being integrally knit to the inner wall, with the other of the opposite edges of the outer wall being wrappable about the inner wall into fixed relation about the inner wall.

In accordance with another aspect of the invention, the yarn forming the outer wall has greater impact resistance relative to the yarn forming the inner wall.

In accordance with another aspect of the invention, the yarn forming the outer wall consists of at least one of polyester, nylon, polypropylene, polyethylene, acrylic, cotton, rayon.

In accordance with another aspect of the invention, the yarn forming the inner wall is a multifilament mineral fiber.

In accordance with another aspect of the invention, the yarn forming the inner wall consists of at least one of silica, fiberglass, ceramic, basalt, slate, slag, aramid and carbon.

In accordance with another aspect of the invention, an impact resistant layer is provided to cover the outer wall.

In accordance with another aspect of the invention, the impact resistant layer forms a circumferentially continuous layer about the inner wall upon wrapping the outer wall about the inner wall.

In accordance with another aspect of the invention, a plurality of fasteners can be fixed to the impact resistant layer, wherein pairs of the plurality of fasteners are fixable to one another to maintain the outer wall in wrapped relation about the inner wall.

In accordance with another aspect of the invention, the impact resistant layer is stitched to the outer wall.

In accordance with another aspect of the invention, the inner wall can be knit with 2×2 rib knit stitches to enhance impact resistance and thermal insulation.

In accordance with another aspect of the invention, a method of constructing a tubular textile sleeve for providing a thermal barrier about an elongate member extending therethrough is provided. The method includes, knitting a circumferentially continuous tubular inner wall having a central cavity extending lengthwise along a central axis between open opposite ends, and knitting an outer wall having opposite edges extending lengthwise in generally parallel relation with the central axis, with one of the opposite edges being knit integrally with the inner wall such that the outer wall extends away from the inner wall, wherein the outer wall is wrappable about the inner wall to form the sleeve having a dual layer wall.

In accordance with another aspect of the invention, the method can further include forming the outer wall with yarn having a greater impact resistance relative to the yarn forming the inner wall.

In accordance with another aspect of the invention, the method can further include forming the outer wall with at least one of polyester yarn, nylon yarn, polypropylene yarn, polyethylene yarn, acrylic yarn, cotton yarn, and rayon yarn.

In accordance with another aspect of the invention, the method can further include attaching an impact resistant layer to the outer wall.

In accordance with another aspect of the invention, the method can further include stitching the impact resistant layer to the outer wall.

In accordance with another aspect of the invention, the method can further include forming the inner wall with a heat resistant mineral yarn, such as from fiberglass, silica, basalt, ceramic, slate, slag, or the like, and forming the outer wall from a different yarn having an increased impact resistance relative to the yarn forming the inner wall.

In accordance with another aspect of the invention, the method can further include knitting the inner wall with 2×2 rib knit stitches.

In accordance with another aspect of the invention, the method can further include knitting the outer wall with other than 2×2 rib knit stitches.

In accordance with another aspect of the invention, the method further includes knitting the inner and outer wall simultaneously together on a flatbed knitting machine.

### BRIEF DESCRIPTION OF THE DRAWINGS

These and other aspects, features and advantages of the present invention will become more readily appreciated when considered in connection with the following detailed description of presently preferred embodiments and best mode, appended claims and accompanying drawings, in which:

FIG. 1 is a schematic isometric view of a knit tubular sleeve constructed in accordance with one aspect of the invention shown in an assembled state with an elongate tubular member to be protected extending through a central cavity bounded by a circumferentially continuous inner wall of the sleeve;

FIG. 1A is a schematic cross-sectional view taken generally along the line 1A-1A of FIG. 1;

FIG. 2A is a view of the sleeve of FIG. 1 shown in a first pre-assembled state, with a radially inwardly facing inner surface of a wrappable outer wall shown;

FIG. 2B is a view similar to FIG. 2A, with a radially outwardly facing outer surface of the wrappable outer wall shown; and

FIG. 3 is a schematic isometric view of the knit tubular sleeve shown in a partially assembled state with the elongate tubular member shown inserted through the central cavity of the circumferentially continuous inner wall of the sleeve, with the wrappable outer wall of the sleeve shown prior to being wrapped about the inner wall.

### DETAILED DESCRIPTION OF PRESENTLY PREFERRED EMBODIMENTS

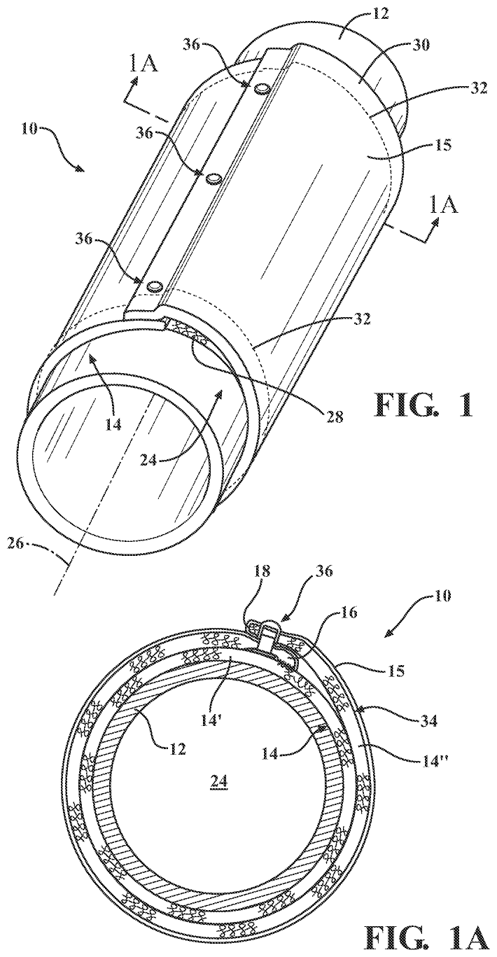

Referring in more detail to the drawings, FIGS. 1 and 1A illustrate a knitted protective tubular sleeve, referred to hereafter as sleeve 10, constructed in accordance with one embodiment of the disclosure shown disposed about contents to be protected, shown as an elongate member 12 to be insulated and protected. The sleeve 10 is protective in that it provides a thermal barrier, particularly to extreme heat, whether preventing heat from radiating radially outwardly, such as from the elongate member 12, e.g. hot conduits or pipes within an engine compartment or an exhaust pipe, contained within the sleeve 10, or providing a protective barrier to an elongate member 12, e.g. wire harness or cable contained within the sleeve 10, against heat from radiating inwardly into the sleeve 10 from nearby hot components, e.g. engine or an exhaust pipe. The sleeve 10 also provides protection against environmental contaminants from entering and/or damaging the sleeve 10 or the contents 12 within the sleeve 10, such as against impact resistance from stone impingement or the like, abrasive debris or abrasive surfaces and liquid contaminants, e.g. fuel, oil, water. The sleeve 10 has an integral, single piece tubular knitted wall 14, which includes a knitted, circumferentially continuous inner wall 14′ and a knitted outer wall 14″, wherein the outer wall 14″ is wrappable about the circumferentially continuous inner wall 14′, wherein the outer wall 14″ is brought into fixed relation about the inner wall 14′ such that the outer wall 14″ extends about the entire outer circumference of the inner wall 14′ to provide protection against impact forces, abrasion, ingress of contamination, and increased thermal insulation about the entirety of the circumference of the inner wall 14′. The inner and outer walls 14′, 14″ are knitted integrally as a single piece in a single knitting process via a flatbed knitting machine, and thus, the finished sleeve 10 can be readily handled as a single product and does not require secondary stitching processes to join the inner and outer walls 14′, 14″ to one another.

The inner and outer walls 14′, 14″ both provide thermal protection; however, an added function of the outer wall 14″ is to provide enhanced mechanical protection to the inner wall 14′ and its contents 12 against abrasion and damage, such as from debris impacting, cutting, and/or abrading the inner wall 14′. Accordingly, the outer wall 14″ prevents the aforementioned debris and abrasive forces from contacting the inner wall 14′. Meanwhile, the primary function of the inner wall 14′ is to provide thermal protection about the elongate member 12, such as by acting as a thermal barrier and/or heatsink to prevent heat from radiating outwardly from the elongate member 12 and radially outwardly from the inner wall 14′, particularly in exhaust pipe applications or other extreme heat applications, including pipes acting as a conduit to high temperature fluids, such as radiator pipes, hoses and the like. By the inner wall 14′ preventing heat from radiating outwardly, other vehicle systems and components are protected against being exposed to the heat flowing through the exhaust pipe 12. Further yet, the outer wall 14″ is protected against exposure to the extreme heat that is blocked by the inner wall 14′, and thus, the yarns used to construct the outer wall 14″ can be provided from different material than the inner wall 14′, such as from yarns having a lower resistance to heat, thereby having different properties, such as a higher impact and/or abrasion resistance than the yarns used to construct the inner wall 14′, as desired.

Further, as is discussed in more detail below, a coating material, also referred to as coating layer 15, having impact resistant, penetration resistant and/or chemical resistant, and abrasion resistant properties can be fixed to cover a radially outwardly facing surface of the outer wall 14″. Accordingly, synergies are provided by the separate inner and outer walls 14′, 14″, in combination with the coating layer 15, wherein each functions to the benefit of the other(s), as well as benefiting functionality of the internal contents 12 of the sleeve 10, thereby providing the sleeve 10 with optimal performance attributes.

The textile sleeve 10 is knitted via a computerized flatbed knitting machine, by way of example and without limitation, having opposing flat beds. With the sleeve wall 14 being constructed on a computerized flatbed knitting machine, the type of knit stitches used to construct the inner and outer walls 14′, 14″ can be different, as desired, for the intended application. Accordingly, the wall 14 can be knit using any type or combination of knit stitches, e.g. jersey, interlock, 2×2 rib forming stitches, or otherwise, such that the inner and outer walls 14′, 14″ may be knit using a single knit stitch or multiple knit stitch types, wherein the types of knit stitches used to form the inner and outer walls 14′, 14″ can be the same or different from one another. Further, the wall 14 can be constructed having any suitable length and diameter, as determined by the diameter provided by the inner and outer walls 14′, 14″. As will be evident to one possessing ordinary skill in the art, the diameter of the tubular inner wall 14′ is controlling, as the outer wall 14″ is ultimately wrapped about the entirety of the circumference of the tubular inner wall 14′.

The outer wall 14″ is knitted as a generally flat piece of material, such as via needles from one of the two knitting beds. The outer wall 14″ has opposite edges 16, 18 extending lengthwise between opposite ends 20, 22. The outer wall 14″ can be knitted using any desired type of yarn material, whether monofilament yarn and/or multifilament yarn, depending on the physical characteristics sought for the application. The yarn used to knit the outer wall 14″ can be less resistant to heat than the yarn used to knit the inner wall 14′ given the inner wall 14′ functions as a primarily barrier to heat, thereby blocking heat from radiating radially outwardly to the outer wall 14″. As such, a yarn more well suited to withstand abrasion and impact forces from external debris can be used to construct the outer wall 14″, thereby resulting in the sleeve 10 being able to both withstand abrasion and debris impact forces from external sources via the outer wall 14″ without sustaining significant damage thereto, while also functioning as an optimal barrier to radiant heat from the hot elongate member 12 via the inner wall 14′. Some yarns believed to be suitable for knitting the outer wall 14″ include polyester, nylon, polypropylene, polyethylene, acrylic, cotton, rayon, and fire retardant (FR) versions of all the aforementioned materials, as desired for the intended application.

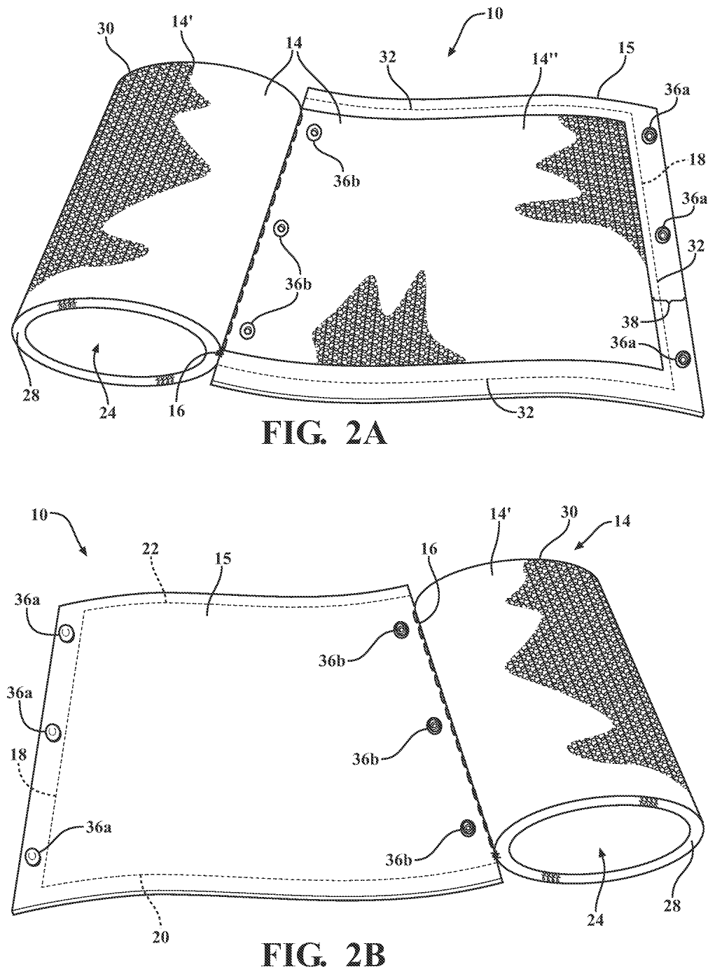

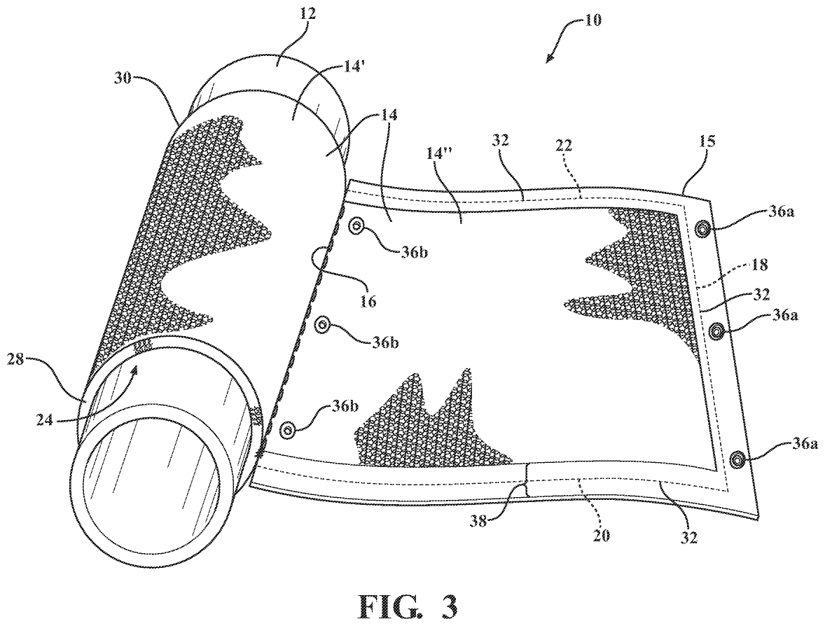

The inner wall 14′ is knitted as a circumferentially continuous tubular wall via both beds of the flatbed knitting machine, with one bed being predominantly responsible for knitting an upper portion or semicircular half (first side) of the inner wall 14′ and the opposite bed being predominantly responsible for knitting a lower portion or semicircular half (second side) of the inner wall 14′, with the two portions being simultaneously knit together in seamless, tubular fashion. During the knitting process, the inner wall 14′ is knitted integrally with the outer wall 14″ as a single piece of material, wherein the embodiment shown in FIGS. 1-3, and best illustrated in FIGS. 2A-3, illustrates the inner wall 14′ knitted integrally with one of the opposite edges 16 of the outer wall 14″, with the opposite edge 18 of the outer wall 14″ being spaced from and extended outwardly from the inner wall 14′ in detached relation therefrom, also referred to as a free end. Being that the inner wall 14′ is circumferentially continuous and seamless, the inner wall 14′ bounds a central cavity 24 that extends lengthwise along a central axis 26 (FIG. 1) between open opposite ends 28, 30. The inner wall 14′ is knitted with one or more yarns that are heat resistant and non-heat-settable, multifilament and/or monofilament, and that are suitable for withstanding extreme temperature environments ranging from between about −60 to 1400 degrees centigrade (° C.). The selected multifilament yarns can be formed with mineral fiber materials, such as silica, fiberglass, ceramic, basalt, slate, slag, aramid or carbon, by way of example and without limitation. The mineral fibers can be provided having a continuous fiber or chopped fiber structure. In some applications of extreme heat, it may be desirable to heat treat the mineral fiber sleeve material to remove organic content therefrom, thereby increasing even more the heat resistance capacity of the sleeve 10. The high heat resistant yarns listed above, although being exceptional for withstanding extreme heat, are generally susceptible to damage if brought into direct contact with abrading and/or impact forces, and thus, the outer wall 14″ is constructed and provided to greatly enhance the resistance to damage of the inner wall 14′ against abrasion and impact forces and to greatly increase the overall durability of the finish sleeve 10.

In addition to the aforementioned materials, if desired, it is contemplated that the same mineral fiber yarn(s) used to construct the inner wall 14′, or different mineral fiber yarn(s), could be used to construct the outer wall 14″, with the coating layer 15 then being applied to the outer wall 14″ after knitting the outer wall 14″. By applying the coating layer 15 to the outer wall 14″, such as a silicone or Teflon layer, by way of example and without limitation, the outer wall 14″ is made impervious to fluid and is made more abrasion and impact resistant, while at the same time providing further enhanced protection against heat from radiating outwardly from the sleeve 10 or radially inwardly into the sleeve 10. The coating layer 15 can be applied to an outer surface 34 of the outer wall 14″ via any suitable fixation mechanism, including high temperature resistant adhesives, and/or a mechanical fixation mechanism, such as stitching 32, by way of example and without limitation. The stitching 32 is shown extending along and adjacent an outer periphery of the outer wall 14″, with an outer edge region 38 of the coating layer 15 being wrapped about the outer periphery of the outer wall 14″, such that the outer periphery of the outer wall 14″ is sandwiched between a radially outwardly facing outermost surface 40 of the coating layer 15 and the wrapped outer edge region 38 of the coating layer 15. The stitching 32 is provided by a strong, tough, high temperature resistant filament, such as via a fiberglass yarn having a PTFE coating, or a metal thread yarn, by way of example and without limitation.

To facilitate maintaining the outer wall 14″ in its wrapped configuration about the tubular inner wall 14′, one or more fastening mechanism(s) can be fixed to the outer wall 14″. In the illustrated example embodiment, a plurality of fasteners, such as snaps 36, by way of example and without limitation, can be fixed to the outer wall 14″ for fixation to one another upon wrapping the outer wall 14″ about the inner wall 14′. It is to be recognized that other types of fastening mechanisms could be used, such as hook-and-loop, by way of example and without limitation. The snaps 36 are arranged with a plurality of female snap portions 36a fixed adjacent the free edge 18, with a corresponding plurality of male snap portions 36b fixed adjacent the opposite edge 16 of the outer wall 14″. It is to be recognized that the reverse relation of any one or all of the female and male snap portions 36a, 36b is contemplated herein. As such, upon disposing the elongate member 12 through the central cavity 24 of the inner wall 14′ (FIG. 3), the outer wall 14″ can be readily wrapped about the inner wall 14′ to bring the corresponding male and female snap portions 36a, 36b into snapping, releasably fixed attachment with one another to maintain the outer wall 14″ in its wrapped configuration.

Many modifications and variations of the present invention are possible in light of the above teachings, as will be readily appreciated by one possessing ordinary skill in the art. It is contemplated that all features of all claims and of all embodiments can be combined with each other, so long as such combinations would not contradict one another. It is, therefore, to be understood that the invention may be practiced otherwise than as specifically described, and that the scope of the invention is defined by any ultimately allowed claims.

1. A wrappable sleeve for providing EMI protection about an elongate member, comprising:
an outer wall of interlaced wire, said outer wall having opposite outer edges extending lengthwise between opposite outer ends;
an inner wall of interlaced yarns fixed to the outer wall, said inner wall having opposite inner edges extending lengthwise between opposite inner ends, the yarns including heat-set yarns biasing said inner and outer edges into overlapping relation with one another, at least some of the yarns having an exposed conductive material bonded thereto.

2. The knit sleeve of claim 1, wherein the yarn forming said knit outer wall has greater impact resistance relative to the yarn forming said inner wall.

3. The knit sleeve of claim 2, wherein the yarn forming said knit outer wall consists of at least one of polyester, nylon, polypropylene, polyethylene, acrylic, cotton, rayon.

4. The knit sleeve of claim 3, wherein the yarn forming said circumferentially continuous, tubular knit inner wall is a multifilament mineral fiber.

5. The knit sleeve of claim 4, wherein the yarn forming said circumferentially continuous, tubular knit inner wall consists of at least one of silica, fiberglass, ceramic, basalt, slate, slag, aramid and carbon.

6. The knit sleeve of claim 1, further including an impact resistant layer covering said outer wall.

7. The knit sleeve of claim 6, wherein the impact resistant layer forms a circumferentially continuous layer about said inner wall upon wrapping said outer wall about said inner wall.

8. The knit sleeve of claim 7, further including a plurality of fasteners fixed to said impact resistant layer, wherein pairs of said plurality of fasteners are fixable to one another to maintain said outer wall in wrapped relation about said inner wall.

9. The knit sleeve of claim 6, wherein the impact resistant layer is stitched to said outer wall.

10. The knit sleeve of claim 1, wherein said inner wall is knit with 2×2 rib knit stitches.

11. A method of constructing a tubular textile sleeve for providing a thermal barrier about an elongate member extending therethrough, comprising:
knitting a circumferentially continuous tubular inner wall having a central cavity extending lengthwise along a central axis between open opposite ends; and
knitting an outer wall having opposite edges extending lengthwise between opposite ends integrally with the inner wall such that the outer wall extends away from the inner wall, wherein the outer wall is wrappable about the inner wall to form the sleeve having a dual layer wall.

12. The method of claim 11, further including fixing an impact resistant layer to a radially outwardly facing outer surface of the outer wall.

13. The method of claim 12, further including stitching the impact resistant layer to the outer wall.

14. The method of claim 12, further including fixing at least fastener to the impact resistant layer, and configuring the at least one fastener to releasably maintain the outer wall in wrappable relation about the inner wall.

15. The method of claim 14, further including fixing a plurality of the at least fastener to the impact resistant layer, and providing each of the plurality of fasteners including a female snap portion and a male snap portion, with the female and male snap portions being configured for snapping, releasably fixed attachment with one another to maintain the outer wall in its wrapped configuration.

16. The method of claim 11, further including forming the outer wall with yarn having a greater impact resistance relative to the yarn forming the inner wall.

17. The method of claim 16, further including forming the outer wall with at least one of polyester yarn, nylon yarn, polypropylene yarn, polyethylene yarn, acrylic yarn, cotton yarn, and rayon yarn.

18. The method of claim 11, further including forming the inner wall with a heat resistant mineral yarn, such as from fiberglass, silica, basalt, ceramic, slate, slag, or the like, and forming the outer wall from a different yarn having an increased impact resistance relative to the yarn forming the inner wall.

19. The method of claim 11, further including knitting the inner wall with 2×2 rib knit stitches.

20. The method of claim 18, further including knitting the outer wall with other than 2×2 rib knit stitches.
